(19) United States
(12) Patent Application Publication
(10) Pub. No.: US 2011/0304483 A1
(43) Pub. Date: Dec. 15, 2011

(54) Method and apparatus for text data input with an alphanumeric keypad for an electronic device

(76) Inventor: Richard Woocheol Moon, Los Angeles, CA (US)

(21) Appl. No.: 12/802,665

(22) Filed: Jun. 10, 2010

(51) Int. Cl. H03K 17/94

(52) U.S. Cl. 341/22

(57) ABSTRACT

An alphanumeric keyboard is provided which includes a 3×4 key button configuration and five function keys. The 3×4, 12 key button and five function keys configuration provides optimal space for the user to conveniently press the desired keys for inputting text into a portable electronic device. The alphanumeric keypad minimizes the number of key presses to input a text message by organizing the alphabet in the order that the characters are most frequently used. To reduce the number of repeated key presses the keys designated by numerals 2-8 each display two alphabet characters, and keys 9, 0, *, and # each display three alphabet characters. The keypad offers two methods of text input via portable communication devices: 1) the conventional multi-tap method of text input; 2) the Alpha mode method.

The conventional multi-tap technique is based on the number of taps, or presses, on a given key, which specifies the desired letter on the key being tapped. For example, to input the alphabet letter “A” the user would tap the key designated by numeral 2, and also displays abc, i.e., 2-ABC. As “A” first letter displayed the user taps once to input the letter “A”, to input the alphabet letter “B” the user would tap the 2 key twice, and to input the alphabet letter “C” the user would tap the 2 key three times. Thus, several key taps are required to input a common word or message, resulting in unnecessary delay.

In the Alpha mode method, the key designated by the numeral 1 displays the Alpha key (α), when pressed Alpha mode is activated. In Alpha mode the alphabet letter corresponding to the first letter displayed on a selected key is input by a user by pressing the corresponding key once. An alphabet letter corresponding to the second letter displayed on a selected key is input by a user by first pressing the Alpha key and secondly pressing the corresponding key to input the selected second letter. An alphabet letter corresponding to the third letter displayed on a selected key is input by a user by first pressing the Alpha key and secondly pressing the corresponding key to input the third letter. This method reduces delay and creates an intuitive method for the user to input alphanumeric symbols in a portable electronic device; the most frequently used letters associated with text communication are all accessible in one key press. It is contemplated that the portable electronic device includes a controller, controlling input of an alphanumeric symbol when a user first presses one of the plurality of function key buttons and second presses a designated key that corresponds to a selected symbol, as well as subsequent key presses.

### FIELD OF THE INVENTION

The present invention relates to an alphanumeric keypad for data input for electronic devices. More specifically, the present invention relates to a method and apparatus for quickly inputting text into an electronic device with a display panel or touchscreen display.

### BACKGROUND OF THE INVENTION

Generally, full sized keyboards are used to quickly and efficiently type data on computer terminals and typewriters. However, full sized keyboards are not compatible with portable electronic devices which accept user data input. Conventional cell phones are designed as flip-phones, slide phones, and standard type phones. The general key button configuration for cell phones is arranged in a 3×4 (row×column) pattern which includes 12 input keys and various function keys. Alphanumeric keypads have been developed to input text in a cell phone, personal assistant device, or other electronic devices.

To quickly input text into a cell phone or other electronic device, the user is required to press more than 36 to 50 keys, including 26 function keys because the English language has 26 characters including vowels and consonants. A cell phone having a full QWERTY keyboard would provide easy to input text, as implemented by a personal computer keyboard, and can reduce the number of times the key buttons are pressed.

Currently, text input using the full QWERTY keyboard is the best method for mobile communication Short Message Service (SMS). However, there are disadvantages to implementing the full QWERTY keyboard into cell phones. For example, the cell phone would require a large number of keys, therefore, the key buttons would be configured smaller due to the limited space on the cell phone. The limited space on the cell phone would reduce the user's delicate sense of physical operation when using the cell phone.

Furthermore, a cell phone including a full QWERTY keyboard increases the cell phone cost and overall weight.

Cell phones that are small sized, lightweight, and inexpensive are not preferred over cell phones containing a full QWERTY keyboard because they do not have enough space for the full QWERTY keyboard to be implemented on the cell phone body.

Typical cell phone keypad designs and methods provide a 12 key keypad designating one of ten numerals 0, 1, 2, 3, 4, 5, 6, 7, 8, 9 and two symbols * and #. Ten of the 12 keys designating numerals 0-9 also display three or four English alphabet letters. These keypad designs require a multi-tap technique wherein the number of taps, or presses, on a given key specifies the desired letter on the key being tapped. For example, to input the alphabet letter “A” the user would tap the key designated by numeral 2, and also displays abc, i.e., 2-ABC. As “A” first letter displayed the user taps once to input the letter “A”, to input the alphabet letter “B” the user would tap the 2 key twice, and to input the alphabet letter “C” the user would tap the 2 key three times. Thus, several key taps are required to input a common word or message. This solution is complicated and overly time-consuming. A key of the conventional keypad has four or five choices of entry. As an average, the user needs to depress a key twice to have her desired character found. When the data to be entered is long and contain many words, the number of depressing motions will be roughly the length of the data multiplied by two. Mistakes are common when entering the data for the user loses track of how many times she has depressed a key for a certain character, or the phone misreads one key depress as two depresses. Therefore, many actions of correction are required to complete a simple entry of data.

Another solution is the so called “T-9” method, which allows the user to depress a key only once and the phone will automatically choose a character from the ones represented by the key. When the user types, the phone is programmed to choose the characters accordingly to the most possible combination of the meaningful ones. For example, the user depresses keys 3, 2 and 8 in order respectively. The key 3 may denote “D,” “E,” or “F,” the key 2 may denote “A,” “B,” or “C,” the key 8 may denote “T”, “U,” or “V.” There are twenty-seven possible combinations for the number “3-2-8. The possible combinations include “DAU” and “EBV” and many other ones, among which only a few have meanings in English. The phone would choose the combination from the most frequently used words as the user's entry. For this example, the phone is programmed to choose “EAT” as the user's entry for it is a meaningful word that is more frequently used among the possible ones. This solution is tedious and error prone. The phone is programmed to guess the users meaning and will guess the wrong word in many instances. These errors happen particularly when the data the user wants to enter have no particular meaning, such as peoples' names and street names or addresses. When an error happens the user is required to change the selected letters or text method, adding unnecessary delay and complexity.

In general, other methods for translating touch-tone signals into alphanumeric data are known. For example, U.S. Pat. No. 3,381,275 describes a translator system utilizing what is known as a “twin depression” translation technique. Furthermore, U.S. Pat. No. 4,427,848 entitled “Telephonic Alphanumeric Data Transmission System” presents a method whereby the alphabetic characters are transmitted by depressing a designated key (e.g., *) a number of times equal to the relative position of the inscription of the character on the key (i.e., the placement division of the alphabetic character), followed by the depression of the key on which the character is inscribed. A return to the numeric mode may be effected by depression of a second designated key (e.g. #).

An additional example of a numeric to alphabet translator is described in U.S. Pat. No. 3,618,038, which uses a “delayed depression” technique, wherein depression of keys having different durations are discriminated. For example, an alphabetic character is represented by first depressing a key indicative of the placement division of the alphabetic character (e.g. the 1 key for Division 3) for a duration longer than a preset limit, e.g., 350 milliseconds. The key inscribed with the particular alphabetic character is thereafter depressed for a duration less than the preset limit. A return to the numeric mode is effected by depressing a fourth symbol (e.g. the 0 key) for a period greater than the preset limit.

Still another example has been proposed whereby an alphabetic mode is entered by depressing a first key (e.g., *), followed by depressing a designated key corresponding to the placement division of a particular alphabetic character (e.g., 1, 2, or 3), followed by depression of the key on which the alphabetic character is inscribed. Moreover, other translation techniques whereby each alphanumeric symbol is represented by a specific sequence of DTMF signals, with each character separated by a specific designated DTMF signal (e.g. #) have been proposed.

Each of the aforementioned translation systems are, in general, slow, cumbersome and unintuitive, in that various combinations of a plurality of keys must be depressed to transmit the alphabetic characters. Most individuals do not possess sufficient manual dexterity or patience to use such systems proficiently. A further problem is inherent in the prior art translations systems, in that the added complexity of the systems creates unavoidable delay.

Recently, electronic designers have introduced touch-screen displays for inputting text into cell phones and other electronic devices. The touch screen display provides the above-mentioned disadvantages for text input. More specifically, the display window is too small to accommodate a full QWERTY keyboard, and does not provide for quick text input.

What is needed is an efficient 3×4 keypad design that is capable of entering alphanumerical data without lengthy actions of selecting the characters and correcting the errors, such that the user may input their desired alphanumerical data in a simple, intuitive and expeditious way for cell phones and other electronic devices.

### SUMMARY OF THE INVENTION

An alphanumeric keyboard is provided which includes a 3×4 key button configuration and five function keys. The 3×4, 12 key button and five function keys configuration provides optimal space for the user to conveniently press the desired keys for inputting text into a portable electronic device.

In an embodiment of the present invention, a mobile communication device having a keypad for efficiently inputting data text is presented. The mobile communication device comprises an alphanumeric keypad configured with a 3×4 key button arrangement comprising twelve keys designating one of 1, 2, 3, 4, 5, 6, 7, 8, 9, *, 0, and #; a first and a second alphabet letter displayed on the keys designated 2, 3, 4, 5, 6, 7, and 8, each designated key button corresponding to the displayed alphabet letters on the key; a first, a second and a third alphabet letter is displayed on the keys designated 9, *, 0, and #, each designated key button corresponding to the displayed alphabet letters on the key; and a plurality of function keys corresponding to specific data input functions of the mobile communication device, wherein an alphabet letter character is input into the cellular mobile phone by pressing one of the keys corresponding to a selected letter displayed on the twelve keys.

Based on recent statistics on text messaging the first alphabet letter displayed on the keys designated 2, 3, 4, 5, 6, 7, 8, 9, *, 0, and # comprises corresponding letters A, D, E, H, I, L, N, O, R, S, and T, wherein the letters are used about 80% when composing an alphanumeric word. The second alphabet letter displayed on the keys designated 2, 3, 4, 5, 6, 7, 8, 9, *, 0, and # comprises displaying corresponding letters B, C, F, G, K, M, P, U, V, W, and Y, wherein the letters are used about 20% when composing an alphanumeric word. Furthermore, the third alphabet letter displayed on the keys designated 9, *, 0, and # comprises displaying corresponding letters Q, X, and Z, wherein the letters are used less than 1% when composing an alphanumeric word.

It is contemplated that the mobile communication device includes an α key (Alpha key) corresponding to the key designated 1, wherein an alphabet letter corresponding to the second letter displayed on a selected key is input by a user by first pressing the Alpha key and secondly pressing the corresponding key to input the selected second letter. It is further contemplated that the mobile communication device includes a controller controlling input of an alphanumeric symbol when a user first presses one of the plurality of function key buttons and second presses a designated key that corresponds to a selected symbol.

It is further contemplated that a user presses a key once to input the first alphabet letter displayed on the key, the user presses the key twice to input the second letter displayed on the key, and the user presses the key three times to input the third letter displayed on the key. It is further contemplated that the user presses down a key for longer than 1 second to select the capital version of the 1^{st} letter displayed on the key. The user presses the key once, then presses the same key again and holds the key down for longer than 1 second to select the capital version of the 2^{nd} letter displayed on the key. Moreover, according to the present invention, a user selects the capital version of the 3^{rd} alphabet letter displayed on a particular key, when a user presses the key twice then presses the key a third time and holds the key down for longer than 1 second.

In another embodiment of the present invention, a method for inputting data text using a keypad for an electronic device is presented. The method includes providing an alphanumeric keypad configured with a 3×4 key button arrangement, the arrangement comprising twelve keys designating one of 1, 2, 3, 4, 5, 6, 7, 8, 9, *, 0, and #; displaying a first and a second alphabet letter on the keys designated 2, 3, 4, 5, 6, 7, and 8, each designated key corresponding to the displayed first and second letter; displaying a first, a second and a third alphabet letter on the keys designated 9, *, 0, and #, each designated key button corresponding to the displayed first, second and third displayed letter; and inputting an alphabet letter character into the electronic device by pressing one of the twelve keys corresponding to a selected letter displayed on the twelve keys.

It is contemplated that the method further includes providing a plurality of function keys that correspond to specific data input functions for the electronic device. It is further contemplated that the method further includes inputting an alphanumeric symbol by first pressing one of the plurality of function key buttons and second pressing a designated key that corresponds to a selected symbol.

In one aspect of the present invention, the alphanumeric keyboard can be configured for inputting characters of various languages, including English, Japanese, Chinese, German, and other languages including each respective distinguished character for each language. It is contemplated that certain Asian based languages that do not use an alphabet as a language character can also use the alphanumeric keypad for mobile SMS communication without inconvenience to the input operation.

The alphanumeric keypad of the present invention is efficiently configured to display the alphabet letters that are most frequently selected on eleven of the 12 keys. A first level of 11 alphabet characters are used about 80% for typical word formation, the second level of 11 set of alphabet characters are used about 20%, and the remaining level of alphabet characters are used less than 1% for text communication. Consequently, 22 alphabet keys are selected almost all the times when composing a word input. The alphanumeric keypad of the present invention requires 1.22 fewer key presses per alphabet using an 11 key alphabet configuration, as compared to conventional cell phone keypads using an 11 key alphabet method the requires 2.14 key presses per alphabet.

### BRIEF DESCRIPTION OF THE DRAWINGS

FIG. 1 shows a data input keypad having a 3×4, 12 key arrangement and five function keys, according to the present invention.

FIG. 2 shows a data input keypad having a 3×4, 12 key arrangement and five function keys and displaying the 11 default alphabet keys, according to the present invention.

FIG. 3 illustrates a key selection sequence for the keypad of FIG. 2, according to the present invention.

FIG. 4 shows a data input keypad having a 3×4, 12 key arrangement and five function keys and displaying the 11 second level alphabet keys, according to the present invention.

FIG. 5 illustrates a key selection sequence for the keypad of FIG. 4, according to the present invention.

FIG. 6 is a front view of a mobile communication device illustrating the alphanumeric keypad configuration, according to the present invention.

FIG. 7 shows a data input keypad having a 3×4, 12 key arrangement and five function keys and displaying the 7 symbols and four alphabet keys, according to the present invention.

FIG. 8 illustrates a symbol key selection sequence for the keypad of FIG. 7, according to the present invention.

FIG. 9 illustrates a center key and alpha key having distinguishing key features, according to another embodiment of the present invention.

FIG. 10 shows a front view of a TV remote control illustrating the alphanumeric keypad, according to another embodiment of the present invention.

FIG. 11 shows four function menus F1, F2, F3 and F4. By tapping the 1, 2, 3, 4, 5, 6, 7, 8, 9, 0, * or # key the 1^{st} value will be selected, if that key is held down for 1 second or longer then the 2^{nd} value will be selected. Blank fields or empty slots indicate no assignment. These fields/slots can be assigned to different values at a later time; keys can be programmed to add or modify symbols and character sets, according to the present invention.

FIG. 12 shows how the F1 menu would look on the screen of a mobile communication device equipped with the alphanumeric keypad configuration, according to the present invention.

FIG. 13 shows how Mathematical symbols can be illustrated with the alphanumeric keypad in the F3 Function, according to the present invention.

FIG. 14 shows how an array of other symbols that can be illustrated with the function menus, such as the F4 menu, according to the present invention. Various symbols and characters can be assigned to different keys within different menus for versatility.

FIG. 15 shows how Korean language characters (left column) can be represented using English equivalents (right column) when utilizing the present invention's alphanumeric keypad design.

FIG. 16 shows how additional foreign language characters and symbols can be illustrated with the F2 Function. Spanish and French characters can be represented with the “F2,” function. Other symbols and characters can be added to additional slots, according to the present invention.

FIG. 17 shows how Japanese language characters (upper column) can be represented using English equivalents (lower column) when utilizing the present invention's alphanumeric keypad design.

### DETAILED DESCRIPTION OF THE INVENTION

The present invention is directed to an alphanumeric keyboard which includes a 3×4 key button configuration and five function keys. The 3×4, 12 key button and five function keys configuration provides optimal space for the user to conveniently press the desired keys for inputting text into a portable electronic device.

The alphanumeric keypad of the present invention is efficiently configured to display the alphabet letters that are most frequently selected on eleven of the 12 keys. A first level of 11 alphabet characters are used about 80% for typical word formation, the second level of 11 set of alphabet characters are used about 20%, and the remaining level of alphabet characters are used less than 1% for text communication. Consequently, 22 alphabet keys are selected almost all the times. The alphanumeric keypad of the present invention provides 1.22 fewer key presses per alphabet using an 11 key alphabet configuration, as compared to conventional cell phone keypads using an 11 key alphabet method the requires 2.14 key presses per alphabet.

The alphanumeric keyboard can be configured for inputting characters of various languages, including English, Japanese, Chinese, German, and other languages including each respective distinguished character for each language. It is contemplated that certain Asian based languages that do not use an alphabet as a language character can also use the alphanumeric keypad for mobile SMS communication without inconvenience to the input operation.

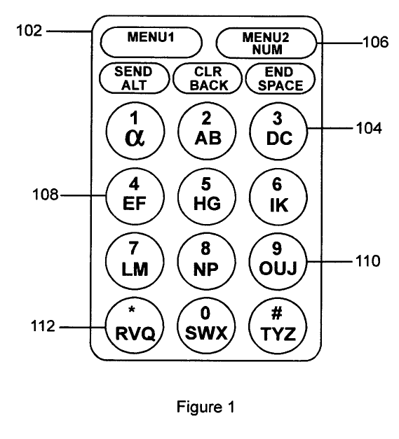

FIG. 1 shows a data input keypad 102 having a 3×4, 12 key 104 arrangement and five function keys 104 according to the present invention.

As illustrated in FIG. 1, the alphanumeric keypad 102 of the present invention minimizes the number of key 104 presses required to input a text message by organizing the alphabets in the order that the characters 110 are frequently are used. To reduce the number of repeated key presses the keys 104 designated by numerals 2-8 each display two alphabet characters 110, and keys 9, 0, *, and # each display three alphabet characters. The two letter alphanumeric keypad 102 arrangement for keys 2-8 includes: 2-AB; 3-DC; 4-EF; 5-HG; 6-IK; 7-LM; and 8-NP. The three letter alphanumeric keys include: 9-OUJ; *-RVQ; 0-S WX; and #-TYZ.

In an embodiment of the present invention, the user presses a key 104 once to input the first alphabet letter 110 displayed on the key, and presses the key twice for the second alphabet letter 110, or three times to input the third alphabet letter 110. Unlike conventional keypads, the present invention eliminates the keypad complexity by arranging two alphabets 110 on a majority of the keys 104. While the 11 numeric keys 104 are used to input alphabet characters, the present invention provides that the typical key is pressed once or twice to input a desired alphabet letter. Therefore, the conventional keypad multi-tap text input method requiring three key presses to cycle through letter selection, is not required when using the alphanumeric keypad 102 of the present invention.

By way of comparison, the following examples illustrate the key selection for a conventional text message input method using a conventional cellular phone keypad including 12 keys designating numbers 0-9, symbols * and #, and displaying three or four alphabet letters on the keys 2-9:

Example Text 1A—Hello
User input/key selection: 44(h) 33(e) 555(1) (time delay to display letter) 555(1) 666(o)
Number of letters input: 5
Number of key strokes: 13
Paused time delay: 1

Example Text 1B—Moon
User input/key selection:
6(m) (time delay to display letter) 666(o)(time delay to display letter) 666(o) (time delay to display letter) 66(n)
Number of letters: 4
Number of key strokes: 9
Paused time delays: 3

Example Text 1C—How are you today?
User input/key selection:
44(h)666(o)9(w)
2(a)777(r)33(e)
999(y)666(o)88(u)
8(t)666(o)3(d)2(a)999(y)
conversation to question mark symbol: 4 strokes(?)
(It is noted that the spaces are disregarded.)
Number of letters: 15
Number of key strokes: 33
Paused time delays: 0

Example Text 1D—What are you doing on Friday?
User input/key selection:
9(w)44(h)2(a)8(t)
2(a)777(r)33(e)
999(y)666(o)88(u)
3(d)666(o)444(i)66(n)4(g)
666(o)66(n)
333(f)777(r)444(i)3(d)2(a)999(y)
conversation to question mark symbol: 4 strokes (?)
Number of letters: 24
Number of strokes: 52
Paused time delay: 1

The conventional cell phone text input method requires repeatedly pressing a key selection to cycle through the desired alphabet displayed on the keys designated by numbers 2 to 9, wherein three or four alphabets are displayed on each of the keys. Thereby, increasing the number of key selections or presses and requiring increased time delay for key selections inputting multiple alphabets displayed on the same key, e.g. 7-PQRS.

If numbers and symbols are considered for each key, one key may designate seven letters and symbols. Therefore, using the conventional data text input method, if it is desired to input the alphabet letter “B”, the user presses the number 2 key twice, but if the key is mistakenly pressed three times, then the letter “C” is input. If the user makes an input correction, the number 2 key is pressed six times to cycle through several symbols to input the correct letter “B”. Further, when the same key is pressed repeatedly a time delay waiting period is required for each repeatedly pressed key.

FIGS. 1-8 illustrate the alpha text keypad arrangements for the present invention. Since one key 104 may designate as many as seven numbers 108, letters 110, and symbols 112, the various alphabets, numbers and symbols are mapped to correspond with the designated key number. A mobile communication device controller, not shown, controls the mobile communication device input for mapping the designated keys 104 with the corresponding alphabet 110, numbers 108, and symbols 112 for each of the 12 keys and the function keys 106.

In one embodiment of the present invention, the user presses a key 104 once to input the first alphabet letter 110 displayed on the key, and presses the key twice for the second alphabet letter or three times to input the third alphabet letter. Unlike conventional keypads, the present invention eliminates the keypad complexity by arranging two alphabet letters 110 on the majority of keys 104. While the eleven numeric keys 104 are used to input alphabet characters, the present invention provides that a key 104 is pressed once to input a desired alphabet letter. Therefore, the conventional keypad multi-tap text input method is not used and less key presses, or selections, are required to input data text using the alphanumeric keypad of the present invention.

In use of the present invention, a default keypad set of keys does not provide for the input of numbers 108 or symbols 112 designated on the key, but instead simplifies the input process by inputting one of the alphabets 110 displayed on the pressed key 104. In the default configuration, the first alphabet letter 110 displayed on a pressed key 104 is input into the communication device 100. To input numerals, as designated by the number 108 displayed on the keys, into the communication device the presses the MENU 2 function key 106 and second presses the designated key 104.

As shown in FIGS. 1, 7 and 9, the first key 104 in the 3×4 keypad configuration designates a number “1” and displays an “a” symbol, i.e., the Alpha key. When a user presses the Alpha key 104 on the keypad 102 and then presses one of the 11 remaining keys 104, the second displayed alphabet 110 is input. For example, the key 104 designated by number 2 displays AB 110. If the user inputs text by pressing the 2 key, then the alphabet letter “A” is input. If the user presses the Alpha key and next presses the 2 key, then the alphabet letter “B” is input. It will be appreciated that there is no additional time delay to input the two displayed letters 110 on a repeatedly pressed key 104, e.g., the 2 key being selected to input both “A” and “B” consecutively in a text message. The consecutive alphabet letter input simplifies text inputting, as compared to the conventional keypad input method.

The Alpha key provides for efficient use of the keypad 102 and easy familiarization with the alphanumeric keypad 102. Since the 26 alphabet letters and the symbols are fixed on the keypad 102, using the Alpha key provides quick recall of the key 104 arrangements without constant visual of the keypad 102 while inputting text. The user's text input speed will increase as the user becomes more familiar with the configuration of the keypad alphabet letter arrangement of the present invention.

To further assist the user in adapting to the alphanumeric keypad of the present invention, a progressive typing game may be uploaded to the communication device 100 to help familiarize the user. It is contemplated that the user will develop text input speeds equal to or great than a skilled user of a full sized QWERTY keyboard.

In a preferred embodiment of the present invention, the alphanumeric text input mode provides a more efficient method for inputting text. There are fewer key strokes required for inputting typical word texts during electronic communication.

As illustrated and defined in FIGS. 1-8, the alphanumeric keypad 102 of the present invention is configured to display the 3×4 key arrangement that provides the two letter alphanumeric key 110 arrangement for keys 2-8 including: 2-AB; 3-DC; 4-EF; 5-HG; 6-IK; 7-LM; and 8-NP, and the three letter alphanumeric keys 110 including: 9-OUJ; *-RVQ; 0-SWX; and #-TYZ.

According to the conventional text input illustrated in Example Text 1A-1D, the conventional cellular phone keypad prevents the user from naturally inputting text smoothly and efficiently, and requires time delayed waiting to input and display consecutive or repeated letters on a key. Those skilled in the art will appreciate that the number of keystrokes required to input text of the present invention is significantly reduced by limiting the number of alphabet letters to two on the seven of the 11 alphanumeric keys 110 on the keypad 102. By way of example, the following text inputs are provided using the alphanumeric keypad text input of the present invention:

Example Text 2A—hello
User input/key selection: 5(h) 4(e) 7(1) (time delay to display letter)
7(1) 9(o)
Number of letters input: 5
Number of key strokes: 5
Paused time delay: 1

Example Text 2B—moon
User input/key selection:
77(m) 9(o) (time delay to display letter) 9(o) 8(n)
Number of letters: 4
Number of key strokes: 5
Paused time delays: 1

Example Text 2C—How are you today?
User input/key selection:
5(h)9(o)00(w)
2(a)*(r)4(e)
##(y)9(o) (time delay to display letter) 99(u)
#(09(o)3(d)2(a)##(y)symbol 2(?)
(It is noted that the spaces are disregarded.)
Number of letters: 15 (plus one symbol)
Number of key strokes: 20
Paused time delays: 1

In another embodiment of the present invention, the user presses a key 104 once to input the first alphabet letter 110 displayed on the key, and presses the key twice to input the second alphabet letter 110 displayed on the key, or three times to input the third alphabet letter 110 displayed on the key. The present invention eliminates keypad complexity by arranging two alphabets on the majority of the keys 104. While the eleven numeric keys 104 are used to input alphabet characters, the present invention provides that a typical key 104 is pressed once to input a desired alphabet letter for composing a word, but it is normally not pressed more than three times for a word composition. The alphabet characters that require three presses on the key 104 are used only 0.45% when a word is composed.

A default keypad set of keys 104 does not provide for the input of numbers 108 or symbols 112 designated on the key 10, but instead simplifies the input process by inputting one of the alphabets displayed on the pressed key. In a default configuration the first alphabet letter 110 displayed on the pressed key 104 is input into the communication device 100.

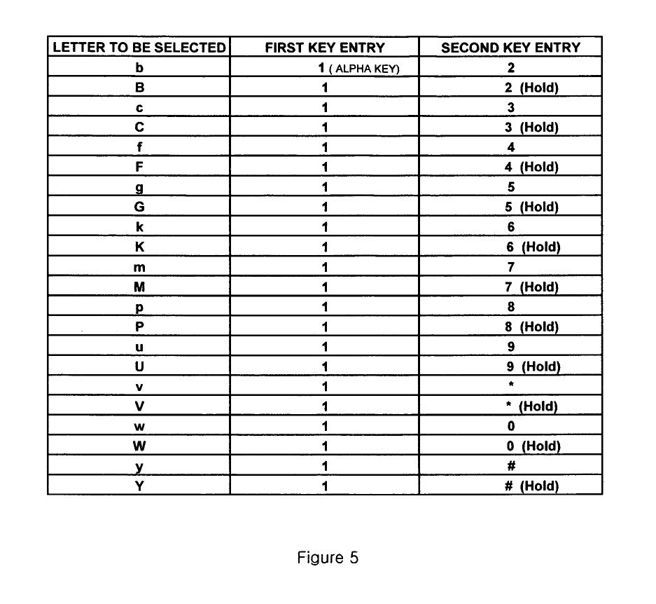

As illustrated in FIGS. 1, 2, and 4 of the present invention, the first alphanumeric key 104 in the 3×4 keypad 102 configuration designates a number “1” and displays an “a” symbol, i.e., the Alpha key. When a user first presses the Alpha key 104 on the keypad and next presses the selected key, the second displayed alphabet letter is input into the communication device, see the key selection sequence of FIG. 5.

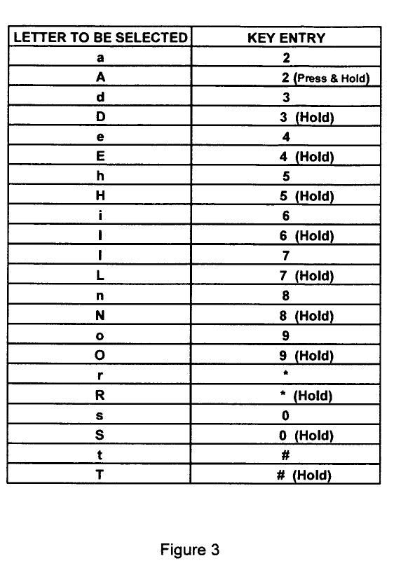

For example, the key 104 designated number 2 displays AB, as shown in FIG. 1. If the user inputs text by pressing the 2 key, then the alphabet letter “A” is input, see FIG. 3. If the user presses the Alpha key and next presses the 2 key, then the alphabet letter “B” is input, see FIG. 5. It will be appreciated that there is no additional time delay to input the two displayed letters on a particular key, e.g., the 2 key being selected to input both “A” and “B” consecutively in a text message. The Alpha key being pressed before repeatedly pressing an alphanumeric key simplifies the text input process by avoiding a time delay waiting period.

The following examples illustrate data text input using the advanced text input ALPHA KEY (“1”):

Example Text 3A—hello
User input/key section:
5(h) 4(e) 7(1) (waiting to be displayed) 7(1) 9(o)
Number of letter: 5
Number of strokes: 5
Paused time delay: 0

Example Text 3B—moon
User input/key section:
17(m) 9(o) 9(o) 8(n)
Number of letter: 4
Number of strokes: 5
Paused time delay: 0

Example Text 3C—how are you today?
User input/key section:
(space are disregarded for this example)
5(h) 9(o) 1(a) 0(w)
2(a)*(r)4(e)
1(a) #(y) 9(o) 1(a) 9(u)
#(t) 9(o) 3(d) 2(a)1 #(y) F1 2(?)
Number of letters: 15
Number of strokes: 20
Paused time delay: 0

As illustrated in FIGS. 5, 7, 8 and as provided above, the advanced text input method of the present invention requires using the Alpha key “1” to greatly reduce the multi-tap, or multi-pressing a key during text input. The Alpha key also eliminates the paused time delay when the user repeatedly presses the same key.

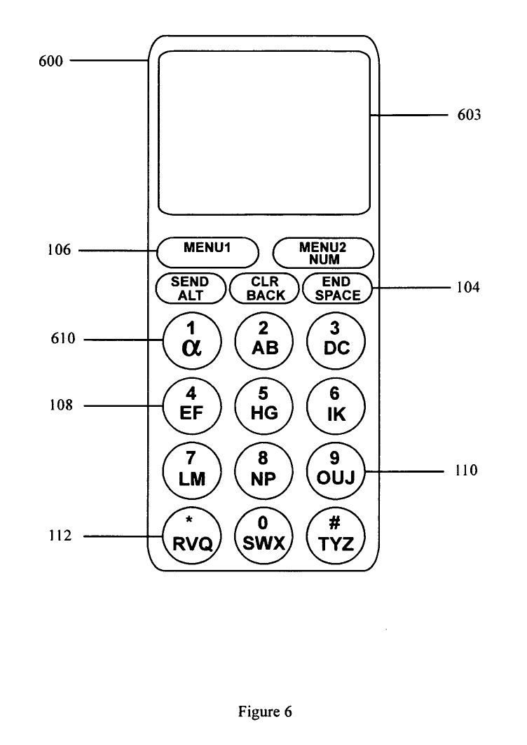

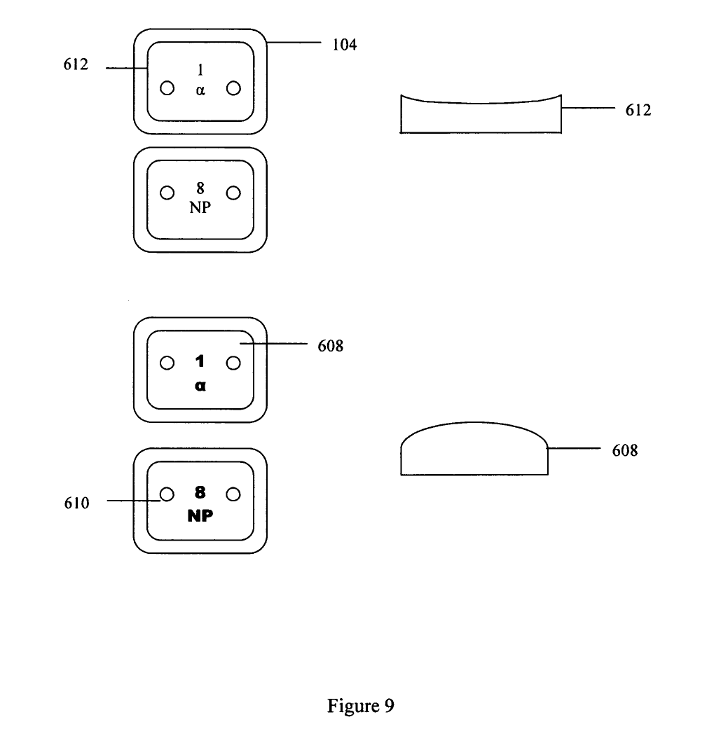

Data input using a cellular phone alphanumeric keypad 602, as illustrated in FIGS. 6 and 9, for Short Message Service (SMS) messaging requires less key strokes than conventional data text input methods. If the user desires to input the letter “A”, press number 2 key 104 once, if the user wants to input the letter “B”, press the number 2 key 104 twice. It is to be appreciated that the cellular phone 600 comprises a display screen 603 for displaying data text input into the cellular phone. It is contemplated that the keypad 602 of the present invention is adaptable for standard mobile phones, flip-phones, slide phones, and other electronic devices including television remote controls, toys, and global position satellite navigation systems.

With reference to FIGS. 5, 7, and 8, symbols 112 are input in text messages by pressing the ALT function key 106 to display a symbol menu 114. When the ALT key 106 is pressed, the symbol menu is displayed on an input screen 603. The ALT key 106 is pressed once to view the 12 symbols on the display screen 603, see FIGS. 6 and 9. The user can select a desired symbol 112 by pressing a designated number key 104 corresponding to the desired input symbol. For example, if the ALT key 106 is repeatedly pressed twice, the user can view alternative symbol menus. If the ALT button is pressed three or four times, the user can view the remaining symbol sets.

Further, the controller may be programmed such that the alternative symbol menus correspond to a particular number key 104.

In another embodiment of the present invention, an advanced text Input method requires pressing the Alpha key “1” to activate as many as two keypads or the ALT key to activate as many as four additional keypads, each having 11 keys 104 corresponding to various alphanumeric alphabet letters 110 and symbol 112 keys. The use of the Alpha key provides for inputting a letter by selecting the Alpha key “1” and ALT Key 106 (function key, send button) instead of all alphabets and symbols on all 12 number keys 104. The keypad 102 is configured using the most frequently used alphabet order on a first level, so it minimizes the movement between the keyboards.

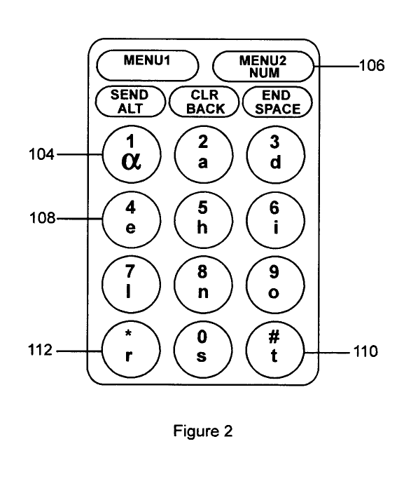

The two main keypads of the present invention include the Alpha key “ON”, i.e., default keypad, Alpha key “OFF” keypad, and the ALT keypad. FIG. 2 illustrates the default data input keypad 102 comprising the most frequently used alphabets configured on a 3×4, 12 key arrangement designated by keys 2-9, *, 0, and #. The alphabet letters of the default keypad includes: ADEHILNORST.

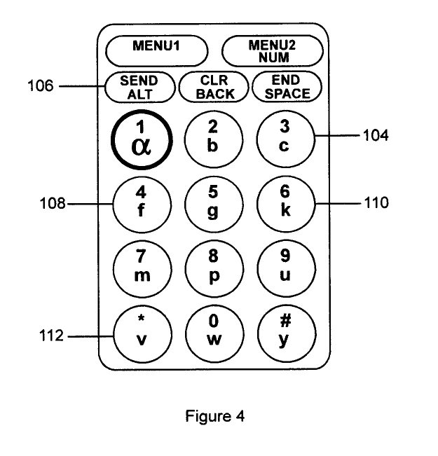

FIG. 4 illustrates the Alpha key “OFF” data input keypad 102 comprising the second level frequently used alphabets 110, BCFGKMPUVWY, configured on a 3×4, 12 key keypad arrangement designated by keys 2-9, *, 0, and #.

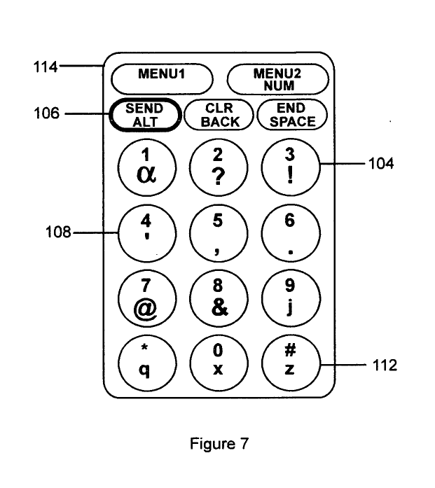

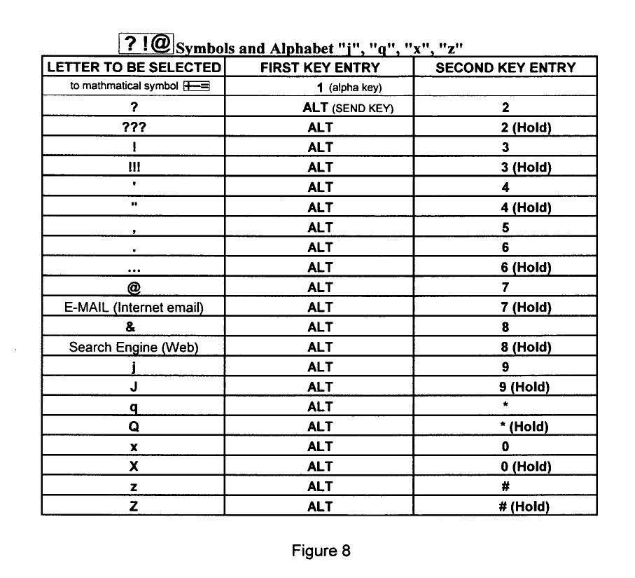

FIGS. 7 and 8 illustrate the keypad symbol key arrangement and a selection sequence configuration, consisting of the most frequently used symbols 112 and the remaining alphabet letters 110, ?!',.@&JQXZ, configured on a 3×4, 12 key 104 keypad arrangement designated by keys 2-9, *, 0, and #.

When using the NUM key 106, if the NUM Key is pressed, the screen 603 is changed to alphanumeric keypad and then, the user presses a corresponding key. After imputing numbers, in order to get back to alphabet letters or symbols, users press NUM symbol again.

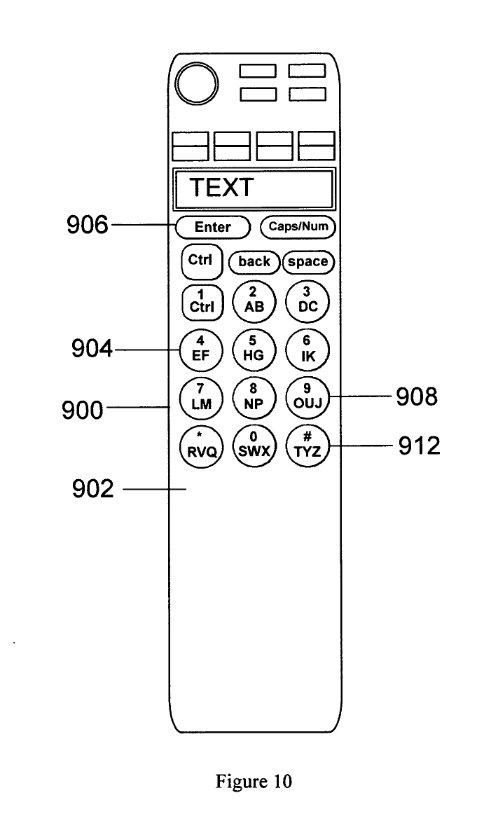

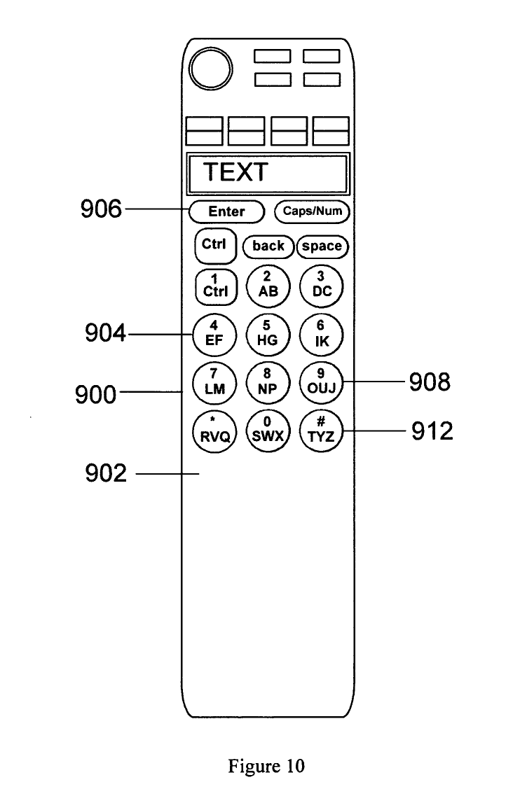

FIGS. 5, 9 and 10 illustrate a center key 604 designed to orient the keypad user with the key layout of the keypad 602 keys 106 and to provide a reference location to the user when operating the keypad. The key designated number 8 “NP” is a center key 604 for the 3×4 key arrangement for of the present invention. The center key 604 may have a different color to distinguish the center key from the other keys 104. Additionally, the Alpha key 604, may be distinguished from the other keys 104 in accordance with the color and composition of the 8 key 604. Like the center key 604, the Alpha key “1” helps the user memorize the surrounding number 2 and 3 key locations. The remaining designated keys 104 are quickly recognized and the user's typing mistakes are reduced. Further, quick familiarization of the keypad layout is established by configuring the number 8 key 604 and the Alpha key 606 with a raised 608, protruding 610, and convex 612 key surfaces, as shown in FIG. 10.

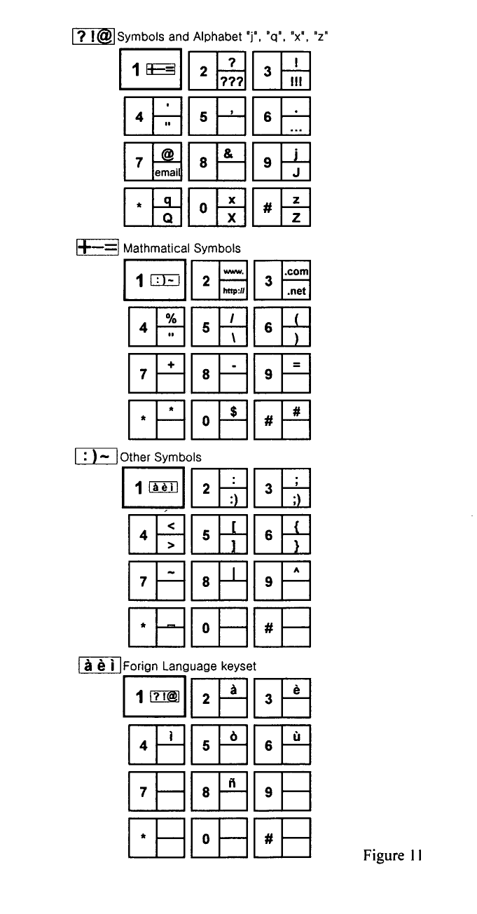

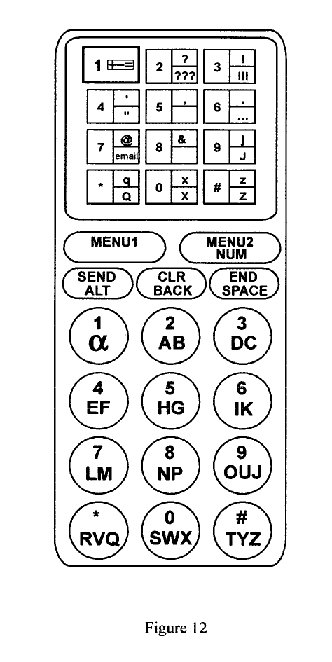

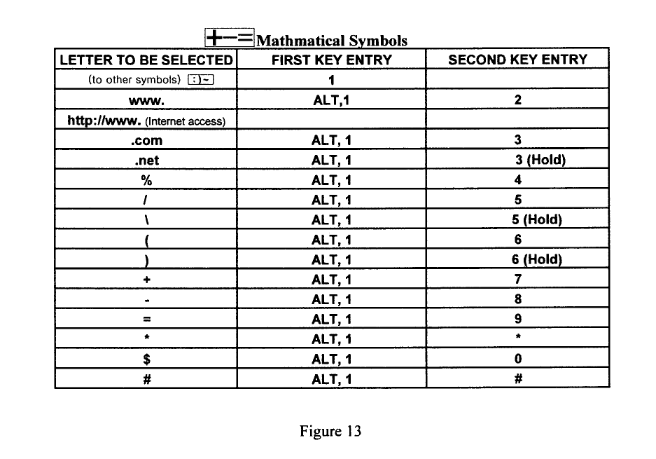

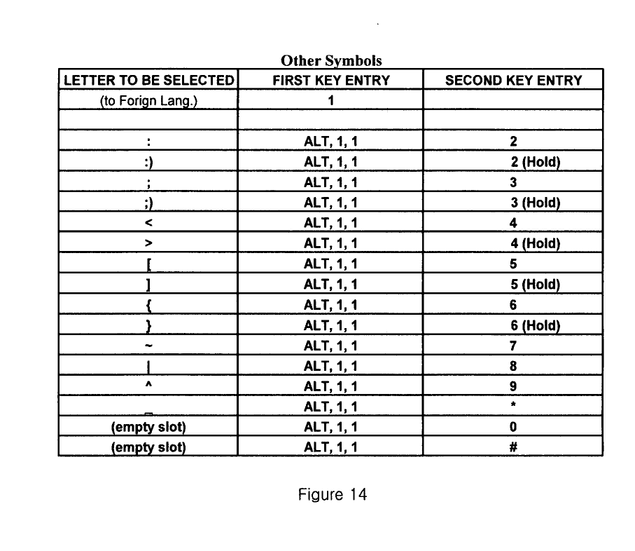

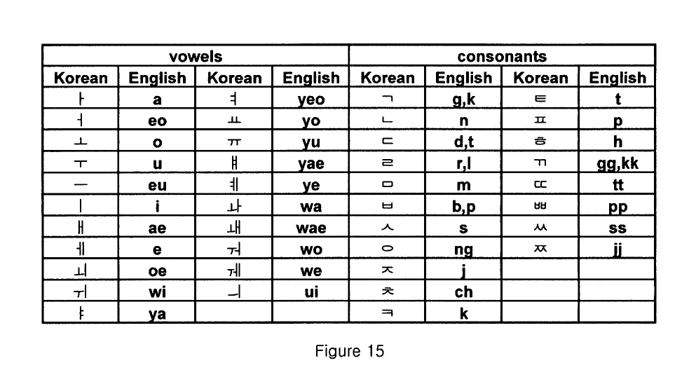

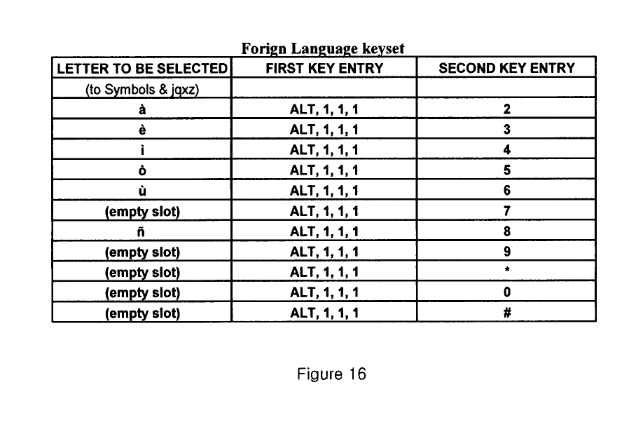

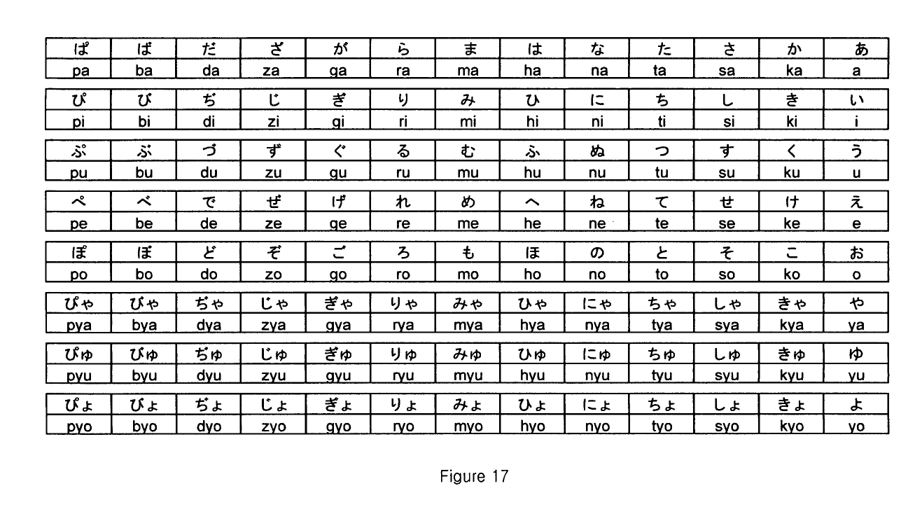

FIG. 11 shows a front view of a TV remote control 900 implementing the alphanumeric keypad 902 configuration, according to another embodiment of the present invention. The TV remote control 900 having the alphanumeric key pad of the present invention further includes a display screen 903 for viewing text input, five function keys 906, a 3×4, and a 12 key 904 arrangement. The keys 904 have numeral designations 908, letters 910 and symbols 912 displayed on the key surface.

The foregoing description of preferred embodiments is presented for purposes of illustration and description. Furthermore, the description is not intended to limit the invention to the form disclosed herein. Accordingly, variants and modifications consistent with the following teachings, and skill and knowledge of the relevant art, are within the scope of the present invention. The embodiments described herein are further intended to explain modes known for practicing the invention disclosed herewith and to enable others skilled in the art to utilize the invention in equivalent, or alternative embodiments and with various modifications considered necessary by the particular application(s) or use(s) of the present invention.

What is claimed is:

1. A method for inputting data text using a keypad for an electronic device, the method comprising:
providing an alphanumeric keypad configured with a 3×4 key button arrangement, the arrangement comprising twelve keys designating one of 1, 2, 3, 4, 5, 6, 7, 8, 9, *, 0, and #;
displaying a first and a second alphabet letter on the keys designated 2, 3, 4, 5, 6, 7, and 8, each designated key corresponding to the displayed first and second letter;
displaying a first, a second and a third alphabet letter on the keys designated 9, *, 0, and #, each designated key button corresponding to the displayed first, second and third displayed letter; and
inputting an alphabet letter character into the electronic device by pressing one of the twelve keys corresponding to a selected letter displayed on the twelve keys.

2. The method of claim 1, further comprising providing a plurality of function keys that correspond to specific numbers and data input functions for the electronic device.

3. The method of claim 2, further comprising inputting an alphanumeric symbol by first pressing one of the plurality of function key buttons and second pressing a designated key that corresponds to a selected symbol.

4. The method of claim 2, further comprising inputting numbers by first pressing NUM symbol and second pressing a corresponding number. After imputing numbers, in order to get back to alphabet letters or symbols, users press NUM symbol again.

5. The method of claim 1, wherein a user presses a key once to input the first alphabet letter displayed on the key, the user presses the key twice to input the second letter displayed on the key, and the user presses the key three times to input the third letter displayed on the key.

6. The method of claim 1, wherein displaying the first alphabet letter on the keys designated 2, 3, 4, 5, 6, 7, 8, 9, *, 0, and # comprises displaying corresponding letters A, D, E, H, I, L, N, O, R, S, and T, wherein the letters are used about 80%.

7. The method of claim 1, wherein displaying the second alphabet letter on the keys designated 2, 3, 4, 5, 6, 7, 8, 9, *, 0, and # comprises displaying corresponding letters B, C, F, G, K, M, P, U, V, W, and Y, wherein the letters are used about 20%.

8. The method of claim 1, wherein displaying the third alphabet letter on the keys designated 9, *, 0, and # comprises displaying corresponding letters J, Q, X, and Z, wherein the letters are used less than 1%.

9. The method of claim 2, further comprising: providing the key designated 1 to correspond to an α key (Alpha key); and inputting an alphabet letter corresponding the second letter displayed on a selected key by first pressing the Alpha key and second pressing the corresponding key to input the selected second letter.

10. The method of claim 9, wherein a default keypad is activated after the selected letter is input after first pressing the Alpha key.

11. The method of claim 9, further comprising:
pressing the ALT key designated SEND to display a first symbol keypad for inputting alphanumeric symbols.

12. The method of claim 11, wherein pressing the ALT key twice displays a second symbol keypad, and pressing the ALT three times displays a third symbol keypad, and pressing the ALT key four times displays a fourth symbol keypad.

13. The method of claim 1, wherein the alphanumeric keyboard provides data input for at least one of a cellular mobile phone, a personal digital assistant, a GPS unit, and a television remote control.

14. A method for efficiently inputting data text using a keypad for an electronic device, the method comprising:
providing an alphanumeric keypad configured with a 3×4 key button arrangement, the arrangement comprising twelve keys designating one of 1, 2, 3, 4, 5, 6, 7, 8, 9, *, 0, and #, wherein a first and a second alphabet letter is displayed on the keys designated 2, 3, 4, 5, 6, 7, and 8, and a first, a second and a third alphabet letter is displayed on the keys designated 9, *, 0, and #, each designated key button corresponding to the displayed alphabet letters o the key;
providing a plurality of function keys correspond to specific data input functions of the electronic device;
providing an α key (Alpha key) on the key designated 1; and
inputting an alphabet letter character into the electronic device by pressing one of the twelve keys corresponding to a selected letter displayed on the twelve keys, wherein:
a user presses a selected key once to input the first alphabet letter displayed on the key;
a user inputs an alphabet letter corresponding the second letter displayed on a selected key by first pressing the Alpha key and second pressing the corresponding alphabet key to input the selected second letter displayed on the selected key; and
a user presses one of the plurality of function keys and the corresponding alphabet key to input the selected third letter displayed on the selected key.

15. The method of claim 14, wherein displaying the first alphabet letter on the keys designated 2, 3, 4, 5, 6, 7, 8, 9, *, 0, and # comprises displaying corresponding letters A, D, E, H, I, L, N, O, R, S, and T, wherein the letters are used about 80%.

16. The method of claim 14, wherein displaying the second alphabet letter on the keys designated 2, 3, 4, 5, 6, 7, 8, 9, *, 0, and # comprises displaying corresponding letters B, C, F, G, K, M, P, U, V, W, and Y, wherein the letters are used about 20%.

17. The method of claim 14, wherein displaying the third alphabet letter on the keys designated 9, *, 0, and # comprises displaying corresponding letters J, Q, X, and Z, wherein the letters are used less than 1%.

18. The method of claim 14, further comprising:
pressing the ALT key designated SEND to display a first symbol keypad for inputting alphanumeric symbols.

19. The method of claim 18, wherein pressing the ALT key twice displays a second symbol keypad, and pressing the ALT key three times displays a third symbol keypad, and pressing the ALT key four times displays a fourth symbol keypad.

20. The method of claim 14, wherein the alphanumeric keyboard provides data input for at least one of a cellular mobile phone, a personal digital assistant, a GPS unit, and a television remote control.

21. A mobile communication device having a keypad for efficiently inputting data text, comprising:
an alphanumeric keypad configured with a 3×4 key button arrangement comprising twelve keys designating one of 1, 2, 3, 4, 5, 6, 7, 8, 9, *, 0, and #;
a first and a second alphabet letter displayed on the keys designated 2, 3, 4, 5, 6, 7, and 8, each designated key button corresponding to the displayed alphabet letters on the key;
a first, a second and a third alphabet letter is displayed on the keys designated 9, *, 0, and #, each designated key button corresponding to the displayed alphabet letters on the key;
a plurality of function keys corresponding to specific data input functions of the cellar mobile phone,
wherein an alphabet letter character is input into the mobile communication device by pressing one of the keys corresponding to a selected letter displayed on the twelve keys.

22. The keypad of claim 21, wherein the first alphabet letter displayed on the keys designated 2, 3, 4, 5, 6, 7, 8, 9, *, 0, and # comprises corresponding letters A, D, E, H, I, L, N, O, R, S, and T, wherein the letters are used about 80%.

23. The keypad of claim 21, wherein the second alphabet letter displayed on the keys designated 2, 3, 4, 5, 6, 7, 8, 9, *, 0, and # comprises displaying corresponding letters B, C, F, G, K, M, P, U, V, W, and Y, wherein the letters are used about 20%.

24. The keypad of claim 21, wherein the third alphabet letter displayed on the keys designated 9, *, 0, and # comprises displaying corresponding letters J, Q, X, and Z, wherein the letters are used less than 1%.

25. The keypad of claim 21, further comprising:
an α key (Alpha key) corresponding to the key designated 1;
wherein an alphabet letter corresponding the second letter displayed on a selected key is input by a user first pressing the Alpha key and second pressing the corresponding key to input the selected second letter.

26. The mobile phone of claim 21, further comprising:
a controller controlling input of an alphanumeric symbol when a user first presses one of the plurality of function key buttons and second presses a designated key that corresponds to a selected symbol.

27. The mobile phone of claim 26, wherein a user presses a key once to input the first alphabet letter displayed on the key, the user presses the key twice to input the second letter displayed on the key, and the user presses the key three times to input the third letter displayed on the key.

28. The keypad of claim 21, further comprising:
when a user presses a certain alphabet symbol for more than one second, the small letter becomes corresponding capital letter, and a certain symbol becomes next symbol or plural symbols.
